(19) United States
(12) Patent Application Publication
(10) Pub. No.: US 2013/0098665 A1
(43) Pub. Date: Apr. 25, 2013

(54) FLEXIBLE PRINTED CIRCUIT BOARD AND PRODUCTION METHOD OF SAME

(71) Applicants: Yuu Ishii, Sakura-shi (JP); Atsuki Nogami, Sakura-shi (JP); Yusuke Nakatani, Sakura-shi (JP)

(72) Inventors: Yuu Ishii, Sakura-shi (JP); Atsuki Nogami, Sakura-shi (JP); Yusuke Nakatani, Sakura-shi (JP)

(21) Appl. No.: 13/655,068

(22) Filed: Oct. 18, 2012

(30) Foreign Application Priority Data
Oct. 21, 2011 (JP) 2011-232010

(51) Int. Cl. H05K 1/02; H05K 3/10; H05K 3/06

(52) U.S. Cl. 174/254; 205/104

(57) ABSTRACT

The present invention is a flexible printed circuit board provided with an insulating substrate and a wiring circuit provided on at least one main surface side of the insulating substrate, wherein the wiring circuit has a laminate having a first metal layer that contains first metallic crystal grains and a second metal layer that is adjacent to the first metal layer and contains second metallic crystal grains, with the first metal layer and the second metal layer being laminated along a direction perpendicular to the main surface of the insulating substrate, and the average grain size of the first metallic crystal grains is smaller than the average grain size of the second metallic crystal grains.

### BACKGROUND OF THE INVENTION

1. Field of the Invention

The present invention relates to a flexible printed circuit board and a production method thereof.

2. Description of the Related Art

Flexible printed circuit boards are used as wiring in hard disks, cell phones, digital still cameras, digital video cameras and the like.

In recent years, flexible printed circuit boards have come to be used particularly in fields requiring high flexibility due to the pliability thereof. For example, flexible printed circuit boards have come to be used for wiring between a magnetic head provided within a hard disk drive and main circuit, wiring connecting the body and moving parts of folding cell phones, and wiring between camera imaging devices and a main circuit board. In such applications, flexible printed circuit boards are required to ensure electrical continuity between equipment or elements while being subjected to repeated bending. Thus, flexible printed circuit boards are required to have superior bending resistance.

The following non-patent document 1 describes the use of rolled copper foil for the conductor of a flexible printed circuit board in order to improve bending resistance of a flexible printed circuit board.

Non-patent Document 1: Yokuwakaru furekishiburu kiban no tsukaikata (Easy Guide to Use of Flexible Circuit Boards) by Kenji Numakura, 1st Edition, Business and Technology Daily News, Jan. 21, 2005, p. 41

### BRIEF SUMMARY OF THE INVENTION

However, the flexible printed circuit board described in the above-mentioned Non-patent Document 1 has the problems indicated below.

Namely, when bending of a small radius of curvature is repeatedly imparted to the flexible printed circuit board of the above-mentioned Non-patent Document 1, the conductor becomes fatigued and deteriorates, and depending on the case, cracks form in the conductor possibly resulting in disconnection. Thus, a flexible printed circuit board is required that has superior bending resistance.

With the foregoing in view, an object of the present invention is to provide a flexible printed circuit board having superior bending resistance and a production method thereof.

When the inventors of the present invention conducted studies on reasons for the occurrence of disconnection in the conductor caused by the formation of cracks in the abovementioned Non-patent Document 1, it was thought that, when the conductor is composed of a single layer composed of rolled copper foil, in the case cracks form in the surface of the conductor, the cracks propagate to the insulating substrate that supports the conductor, and disconnection occurs as a result thereof. Here, the inventors of the present invention also considered the use of a laminate consisting of multiple layers of metal foil for the conductor. In this case, the progression of cracks formed in the surface of the conductor is interrupted at the interface between adjacent metal foil layers, thereby inhibiting the progression of cracks to the lowermost layer. However, flexible printed circuit boards employing a metal foil laminate for the conductor still had room for improvement with respect to bending resistance. Therefore, as a result of conducting additional extensive studies, the inventors of the present invention found that the above-mentioned problems can be solved by alternately laminating layers having different average grain sizes of their metallic crystal grains, thereby leading to completion of the present invention.

Namely, the present invention is a flexible printed circuit board provided with an insulating substrate and a wiring circuit provided on at least one main surface side of the insulating substrate, wherein the wiring circuit has a laminate having a first metal layer that contains first metallic crystal grains and a second metal layer that is adjacent to the first metal layer and contains second metallic crystal grains, with the first metal layer and the second metal layer being laminated along a direction perpendicular to the main surface of the insulating substrate, and the average grain size of the first metallic crystal grains is smaller than the average grain size of the second metallic crystal grains.

According to this flexible printed circuit board, even if the flexible printed circuit board is subjected to repeated bending, cracks form in the surface of a wiring circuit on the opposite side from the main surface of an insulating substrate due to fatigue of the wiring circuit, and those cracks progress to the insulating substrate side of the laminate, the progression of cracks is inhibited in the first metal layer. Consequently, the flexible printed circuit board of the present invention is able to have superior bending resistance. Namely, a long service life can be realized by the flexible printed circuit board of the present invention.

The reason for the progression of cracks being inhibited in the first metal layer as described above was surmised by the inventors of the present invention to be as indicated below. Namely, although cracks progress along crystal grain boundaries, the progression of cracks is temporarily interrupted at regions where the crystal grain boundaries intersect. In addition, the inventors of the present invention surmised that, in the first metal layer where crystal grain size is extremely small, since there are many regions where crystal grain boundaries intersect, there are many locations where the progression of cracks is interrupted, thereby preventing cracks from progressing easily. In addition, although cracks are thought to easily progress towards the insulating substrate when the average length of those interfaces between adjacent metallic crystal grains that extend toward the insulating substrate is large, if the average grain size of the first metallic crystal grains is smaller than the average grain size of the second metallic crystal grains, the average length of those grain boundaries between adjacent metallic crystal grains that extend towards the insulating substrate can be decreased. Consequently, it was surmised by the inventors of the present invention that the progression of cracks is inhibited in the first metal layer where the average grain size of metallic crystal grains is smaller.

The length in a direction parallel to the main surface of the insulating substrate in the first metallic crystal grains and the second metallic crystal grains is preferably greater than the length along a direction perpendicular to the main surface of the insulating substrate in 50% or more of the first metallic crystal grains and the second metallic crystal grains. Here, “50% or more of the first metallic crystal grains and the second metallic crystal grains” refers to an area percentage, which is the proportion of the area occupied by first metallic crystal grains in which the length in a direction parallel to the main surface of the insulating substrate in the first metallic crystal grains is greater than the length along a direction perpendicular to the main surface of the insulating substrate among the total area of the first metallic crystal grains, being 50% or more, and an area percentage, which is the proportion of the area occupied by second metallic crystal grains in which the length in a direction parallel to the main surface of the insulating substrate in the second metallic crystal grains is greater than the length along a direction perpendicular to the main surface of the insulating substrate among the total area of the second metallic crystal grains, being 50% or more.

Cracks normally progress through grain boundaries between adjacent metallic crystal grains. At this time, cracks are thought to progress easily towards the insulating substrate if the average length of those grain boundaries between adjacent metallic crystal grains that extend towards the insulating substrate is large. With respect to this point, if the length in a direction parallel to the main surface of the insulating substrate in the first metallic crystal grains and the second metallic crystal grains is greater than the length along a direction perpendicular to the main surface of the insulating substrate in 50% or more of the first metallic crystal grains and the second metallic crystal grains, the average length of those grain boundaries between adjacent metallic crystal grains that extend towards the insulating substrate can be further decreased. Consequently, in comparison with the case of the length in a direction parallel to the main surface of the insulating substrate being equal to or less than the length along a direction perpendicular to the main surface of the insulating substrate in 50% or more of the first metallic crystal grains and the second metallic crystal grains, the progression of cracks is sufficiently inhibited and durability of the flexible printed circuit board can be made better.

In the above-mentioned flexible printed circuit board, it is preferable that the laminate have five or more layers each consisting of the first metal layer and five or more layers each consisting of the second metal layer, and in the laminate, the first metal layers and the second metal layers be alternately laminated.

In this case, even if cracks form in the surface of a wiring circuit on the opposite side from the main surface of the insulating substrate, the progression of those cracks can be more effectively inhibited.

In addition, in the above-mentioned flexible printed circuit board, the first metal layer and the second metal layer are preferably copper alloy foil containing 0.05% by weight or more of at least one type of element selected from the group consisting of Sn, Zn, Be, Cd, Ag and Nb.

If the content of the above-mentioned elements in the copper alloy foil is within the range of 0.05% by weight or more, in comparison with the case of the content thereof being less than 0.05% by weight, there is the advantage of being able to set the recrystallization temperature of the copper alloy higher than the temperature of heat treatment during production of the flexible printed circuit board.

In addition, the present invention is a production method of a flexible printed circuit board provided with an insulating substrate and a wiring circuit provided on at least one main surface side of the insulating substrate, this method comprising a seed layer formation step of forming a seed layer on at least one main surface side of the insulating substrate; a plating resist formation step of forming a plating resist in which an opening that has a shape corresponding to the wiring circuit and exposes the seed layer is formed on the seed layer; a wiring circuit formation step of forming the wiring circuit on the seed layer by applying a pulsed current density at least once between the seed layer and an electrode by means of electroplating; a plating resist stripping step of stripping the plating resist; and a seed layer removal step of removing a portion of the seed layer covered by the plating resist, wherein the wiring circuit has a laminate having a first metal layer that contains first metallic crystal grains and a second metal layer that is adjacent to the first metal layer and contains second metallic crystal grains, with the first metal layer and the second metal layer being laminated along a direction perpendicular to the main surface of the insulating substrate, and the average grain size of the first metallic crystal grains is smaller than the average grain size of the second metallic crystal grains.

In addition, the present invention is a production method of a flexible printed circuit board provided with an insulating substrate and a wiring circuit provided on at least one main surface side of the insulating substrate, this method comprising: a seed layer formation step of forming a seed layer on at least one main surface side of the insulating substrate; a plating layer formation step of forming a plating layer on the seed layer by applying a pulsed current density at least once between the seed layer and an electrode by means of electroplating; an etching resist formation step of forming on the plating layer an etching resist in which an opening is formed that exposes the plating layer and which has a shape corresponding to the wiring circuit; a wiring circuit formation step of forming the wiring circuit by etching the exposed plating layer and the seed layer; and a resist stripping step of stripping the etching resist, wherein the plating layer has a laminate having a first metal layer that contains first metallic crystal grains and a second metal layer that is adjacent to the first metal layer and contains second metallic crystal grains, with the first metal layer and the second metal layer being laminated along a direction perpendicular to the main surface of the insulating substrate, and the average grain size of the first metallic crystal grains is smaller than the average grain size of the second metallic crystal grains.

According to these production methods, even if the resulting flexible printed circuit board is subjected to repeated bending, cracks form in the surface of a wiring circuit on the opposite side from the main surface of an insulating substrate due to fatigue of the wiring circuit, and those cracks progress to the insulating substrate side of the laminate, the progression of cracks is inhibited in the first metal layer. Consequently, according to the production method of a flexible printed circuit board of the present invention, a flexible printed circuit board can be obtained that has superior bending resistance.

In the above-mentioned production method of a flexible printed circuit board, the maximum value of the pulsed current density is preferably 4.0 A/dm² or less.

In this case, in comparison with the case of the maximum value of the pulsed current density exceeding 4.0 A/dm², there are the advantages of being able to obtain a fine wiring circuit having superior mechanical strength and of making it easier to obtain a layered crystal structure.

In the above-mentioned production method of a flexible printed circuit board, the pulsed current density is preferably applied five times or more.

In this case, a wiring circuit can be formed that is composed of a laminate having five or more layers each consisting of the first metal layer and five or more layers each consisting of the second metal layer and in which the first metal layers and the second metal layers are alternately laminated.

According to the present invention, a flexible printed circuit board having superior bending resistance, and a production method thereof, are provided.

### BRIEF DESCRIPTION OF THE DRAWINGS

FIG. 1 is a cross-sectional view showing an embodiment of a flexible printed circuit board according to the present invention;

FIG. 2 is a partially enlarged cross-sectional view of FIG. 1;

FIG. 3 is a cross-sectional view showing a seed layer formation step in an embodiment of the production method of a flexible printed circuit board according to the present invention;

FIG. 4 is a cross-sectional view showing a step of arranging a mask on a resist formed on a seed layer in an embodiment of the production method of a flexible printed circuit board according to the present invention;

FIG. 5A and FIG. 5B are cross-sectional views each showing a plating resist formation step in an embodiment of the production method of a flexible printed circuit board according to the present invention;

FIG. 6 is a cross-sectional view showing a wiring pattern formation step in an embodiment of the production method of a flexible printed circuit board according to the present invention;

FIG. 7A is a drawing showing the relationship between each plating time period and the laminate formed;

FIG. 7B is a drawing showing the relationship between plating time and current density during formation of a laminate;

FIG. 8 is a cross-sectional view showing a plating resist stripping step in an embodiment of the production method of a flexible printed circuit board according to the present invention;

FIG. 9 is a cross-sectional view showing a seed layer removal step in an embodiment of the production method of a flexible printed circuit board according to the present invention;

FIG. 10 is a cross-sectional view showing a protective cover laminating step in an embodiment of the production method of a flexible printed circuit board according to the present invention;

FIG. 11 is a cross-sectional view showing a flexible printed circuit board obtained according to the production method of a flexible printed circuit board according to the present invention;

FIG. 12 is a cross-sectional view showing a plating layer formation step in another embodiment of the production method of a flexible printed circuit board according to the present invention;

FIG. 13 is a cross-sectional view showing an etching resist formation step in another embodiment of the production method of a flexible printed circuit board according to the present invention;

FIG. 14 is a graph showing the relationship between plating time and current density when forming a laminate in Example 1;

FIG. 15 is an SEM micrograph showing a cross-section of a laminate in Example 1;

FIG. 16 is a graph showing the results of an MIT folding endurance test for flexible printed circuit boards of Example 1 and Comparative Examples 1 and 2; and

FIG. 17 is a graph showing the results of an IPC bending test for flexible printed circuit boards of Example 1 and Comparative Examples 1 and 2.

### DETAILED DESCRIPTION OF THE INVENTION

The following provides a detailed explanation of embodiments of the present invention.

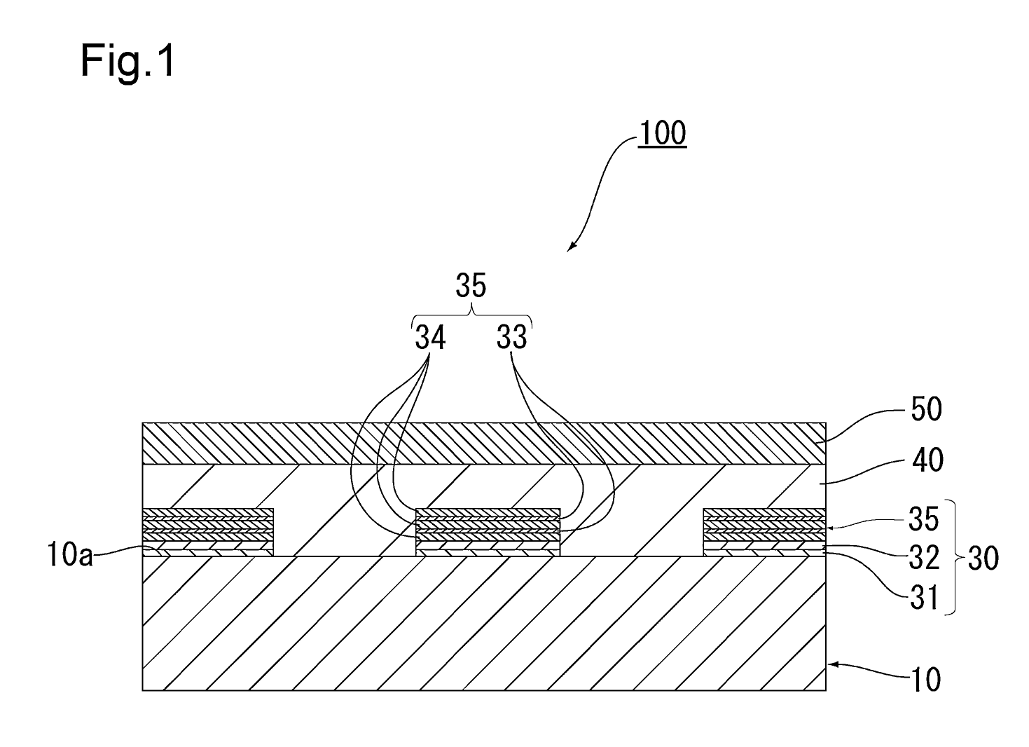

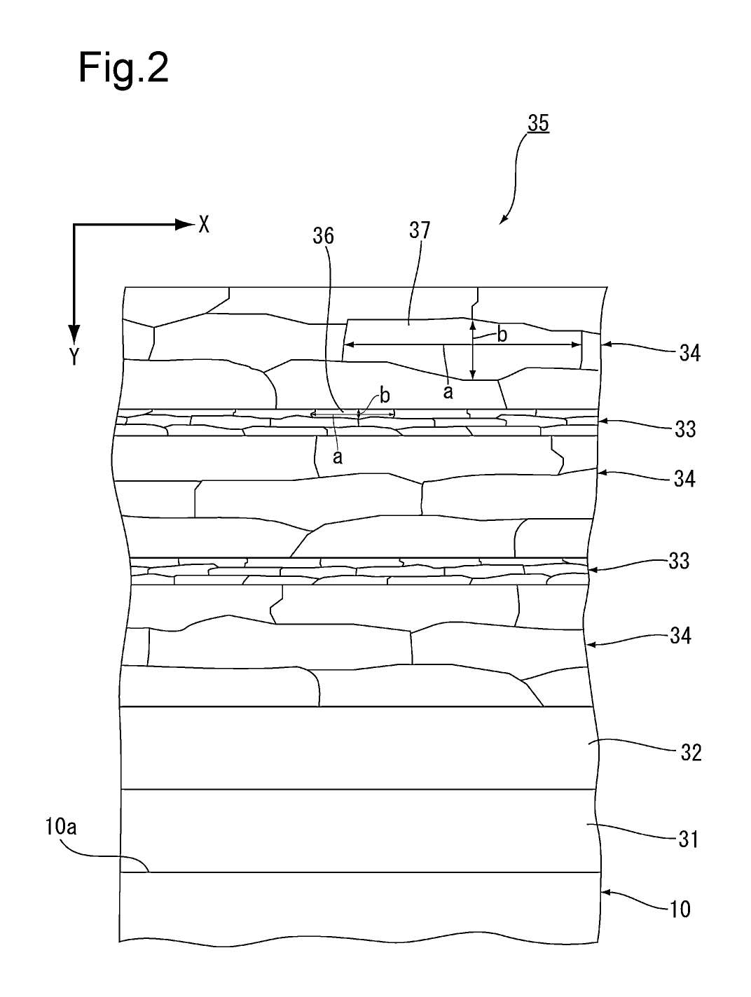

FIG. 1 is a cross-sectional view showing an embodiment of a flexible printed circuit board according to the present invention, and FIG. 2 is a partially enlarged cross-sectional view of FIG. 1. As shown in FIG. 1, a flexible printed circuit board 100 is provided with a first insulating substrate 10, a wiring circuit 30 provided on a main surface 10a of the first insulating substrate 10, an adhesion layer 40 provided so as to cover the wiring circuit 30, and a second insulating substrate 50 provided on the adhesion layer 40.

The wiring circuit 30 is provided with a metal thin film 31 provided on the main surface 10a of the first insulating substrate 10, a metal thin film 32 provided on the metal thin film 31, and a laminate 35 provided on the metal thin film 32. The laminate 35 has a plurality of first metal layers 33 and a plurality of second metal layers 34, and in the laminate 35, the first metal layers 33 and the second metal layers 34 are alternately laminated along a direction Y perpendicular to the main surface 10a of the first insulating substrate 10. The second metal layer 34 closest to the insulating substrate 10 among the plurality of the second metal layers 34 contacts the metal thin film 32.

As shown in FIG. 2, in the laminate 35, the first metal layers 33 contain first metallic crystal grains 36, and the second metal layers 34 contain second metallic crystal grains 37. Here, the average grain size of the first metallic crystal grains 36 in the first metal layers 33 is smaller than the average grain size of the second metallic crystal grains 37 in the second metal layers 34. Furthermore, average grain size refers to the average value of the first metallic crystal grains 36 or the second metallic crystal grains 37. Here, grain size c is represented by the following formula when grain size is taken to be c, length in a direction parallel to the main surface 10a of the first insulating surface 10 is taken to be a, and length in a direction perpendicular to the main surface 10a is taken to be b.

c=(a+b)/2

The length a in a direction X parallel to the main surface 10a of the first insulating substrate 10 refers to the maximum length of a line segment between intersection points of a contour line of the first metallic crystal grains 36 or the second metallic crystal grains 37 and a straight line parallel to the main surface 10a of the first insulating substrate 10. In addition, the length b in a direction Y perpendicular to the main surface 10a refers to the maximum length of a line segment between intersecting points of a contour line of the first metallic crystal grains 36 or the second metallic crystal grains 37 and a straight line perpendicular to the main surface 10a of the first insulating substrate 10.

Average grain size refers to a value measured in accordance with JIS H0501: “Methods for Estimating Average Grain Size of Wrought Copper and Copper Alloys” (corresponding international standard: ISO 2624-1973: “Copper and copper alloys—Estimation of average grain size”). More specifically, the cutting method is used to determine average grain size. Average grain size is determined in the manner indicated below with the cutting method. Namely, after precision polishing a cross-sectional surface of the laminate 35, etching is carried out for several seconds to several tens of seconds using an etching solution which yields different crystal grains and grain boundary etching rates. The cross-section of the laminate 35 obtained in this manner is then observed with a scanning electron microscope to directly measure crystal grain size. Here, in the case of observing the structure of copper and copper alloys, a mixed solution of ammonium hydroxide and hydrogen peroxide is used for the etching solution. Furthermore, details regarding JIS H0501: “Methods for Estimating Average Grain Size of Wrought Copper and Copper Alloys” can be viewed at the web site of the Japanese Industrial Standards Committee (JISC) (http://www.jisc.go.jp).

Moreover, in the flexible printed circuit board 100, although the laminate 35 has a plurality of the first metal layers 33, the first metallic crystal grains 36 of the first metal layers 33 have a smaller average grain size than the average grain size of the second metallic crystal grains 37 of the adjacent second metal layers 34, and in the plurality of first metal layers 33, the average grain size of the first metallic crystal grains 36 may be the same or different. Similarly, in the flexible printed circuit board 100, although the laminate 35 has a plurality of the second metal layers 34, the second metallic crystal grains 37 of the second metal layers 34 have a larger average grain size than the average grain size of the first metallic crystal grains 36 of the adjacent first metal layers 33, and in the plurality of second metal layers 34, the average grain size of the second metallic crystal grains 37 may be the same or different.

According to this flexible printed circuit board 100, even if the flexible printed circuit board 100 is subjected to repeated bending, cracks form in the surface of the wiring circuit 30 on the opposite side from the main surface 10a of the first insulating substrate 10 due to fatigue of the wiring circuit 30, and those cracks progress to the side of the first insulating substrate 10 of the laminate 35, the progression of those cracks is inhibited in the first metal layers 33 having a smaller average grain size of the metallic crystal grains thereof. Consequently, the flexible printed circuit board 100 is able to have superior bending resistance. Namely, the flexible printed circuit board 100 is able to realize a long service life.

Next, a detailed explanation is provided of the first insulating substrate 10, the wiring circuit 30 and the second insulating substrate 50.

(First Insulating Substrate and Second Insulating Substrate)

A polyimide film or polyethylene terephthalate (PET) film and the like are used for the first insulating substrate 10 and the second insulating substrate 50.

(Wiring Circuit)

Although examples of metals that compose the first metal layers 33 and the second metal layers 34 of the wiring circuit 30 include copper and copper alloys, copper alloys are used preferably due to their low electrical resistance. The copper alloys are alloys of copper and other metals. In this case, examples of other metals include Sn, Zn, Be, Cd, Ag and Nb. One type of these metals can be used alone or two or more types can be used in combination. Here, the content of other metal in the copper alloy is preferably 0.05% by weight or more. If the content of other metal is within the above-mentioned range, there is the advantage of being able to set the recrystallization temperature of the copper alloy higher than the temperature of heat treatment during production of the flexible printed circuit board 100 as compared with the case of the content of other metal being less than 0.05% by weight. However, the content of other metal is preferably 0.5% by weight or less and more preferably 0.2% by weight or less. If the content of other metal is within the above-mentioned ranges, there is the advantage of electrical resistance of the copper alloy being able to be further reduced or a more pliable copper alloy film being able to be obtained as compared with the case of the content of other metal exceeding 0.5% by weight.

Although there are no particular limitations on the average grain size of the first metallic crystal grains 36 provided it is smaller than the average grain size of the second metallic crystal grains 37, the ratio of the average grain size of the second metallic crystal grains 37 to the average grain size of the first metallic crystal grains 36 is preferably 2 to 20 and more preferably 5 to 20. In this case, the progression of cracks is more effectively inhibited as compared with the case of the ratio of the average grain size of the second metallic crystal grains 37 to the average grain size of the first metallic crystal grains 36 being outside the above-mentioned ranges.

The average grain size of the first metallic crystal grains 36 is preferably less than 1 μm and more preferably 0.1 μm to 0.5 μm. In this case, the progression of cracks can be inhibited more effectively as compared with the case of the average grain size of the first metallic crystal grains 36 being 1 μm or more.

In 50% or more of the first metallic crystal grains 36 and the second metallic crystal grains 37, the first metallic crystal grains 36 and the second metallic crystal grains 37 are layered, and the length a in a direction X parallel to the main surface 10a of the first insulating substrate 10 is preferably greater than the length b in a direction Y perpendicular to the main surface 10a.

Cracks normally progress through grain boundaries between adjacent metallic crystal grains. At this time, if the average length of those crystal boundaries between adjacent metallic crystal grains that extend towards the first insulating substrate 10 is large, cracks are thought to easily progress towards the side of the first insulating substrate 10. With respect to this point, if 50% or more of the first metallic crystal grains 36 and the second metallic crystal grains 37 are layered and the length a in a direction X parallel to the main surface 10a of the first insulating substrate 10 in the first metallic crystal grains 36 and the second metallic crystal grains 37 is greater than the length b along a direction Y perpendicular to the main surface 10a of the first insulating substrate 10, the average length of those grain boundaries between adjacent metallic crystal grains that extend towards the first insulating substrate 10 can be made smaller. Consequently, in comparison with the case of the average value of the length a in a direction X parallel to the main surface 10a of the first insulating substrate 10 in the first metallic crystal grains 36 and the second metallic crystal grains 37 being equal to or less than the average value of the length b along a direction Y perpendicular to the main surface 10a of the first insulating substrate 10, the progression of cracks is more sufficiently inhibited and durability of the flexible printed circuit board 100 can be made even more superior.

The first metallic crystal grains 36 and the second metallic crystal grains 37 that are layered and in which the length a in a direction X parallel to the main surface 10a of the first insulating substrate 10 is greater than the length b in a direction Y perpendicular to the main surface 10a are each present preferably at a ratio of 50% or more, more preferably at a ratio of 80% or more, and most preferably at a ratio of 100% in the first metal layers 33 and the second metal layers 34, respectively.

In addition, the laminate 35 preferably has 5 or more layers each of the first metal layers 33 and the second metal layers 34. In this case, even if the flexible printed circuit board 100 is subjected to repeated bending and cracks form in the wiring circuit 30, the progression of those cracks can be more efficiently inhibited.

However, in the laminate 35, the numbers of the first metal layers 33 may be at least one layer and the second metal layers 34 may also be at least one layer, or as shown in FIG. 1 and FIG. 2, the numbers of the first metal layers 33 may be less than five layers and the second metal layers 34 may also be less than five layers.

The following provides an explanation of a production method of the above-mentioned flexible printed circuit board 100.

First, the first insulating substrate 10 is prepared.

Next, the wiring circuit 30 is formed on the first insulating substrate 10. The wiring circuit 30 is formed by, for example, electroplating. Although semi-additive processes and subtractive processes are known to be used for electroplating, in the following an explanation of a method of forming the wiring circuit 30 using a semi-additive process is provided.

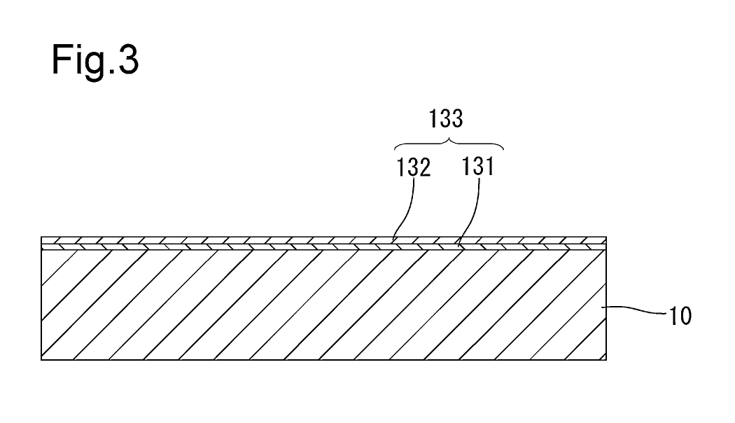

First, as shown in FIG. 3, a seed layer 133, which composes the cathode of the pair of electrodes used when carrying out electroplating, is formed (seed layer formation step). The seed layer 133 can be obtained by forming a first seed layer 131 on the first insulating substrate 10, followed by forming a second seed layer 132 on the first seed layer 131. The first seed layer 131 and the second seed layer 132 can be formed by sputtering, for example. Ni, Cr, Ni—Cr alloy, Ni—Cu alloy or Cr—Cu alloy, for example, are used for the first seed layer 131, while copper, for example, is used for the second seed layer 132. The thickness of the first seed layer 131 is, for example, 0.01 μm to 0.2 μm, while the thickness of the second seed layer 132 is, for example, 0.5 μm to 4.0 μm.

Thus, the seed layer 133 is formed that functions as a cathode used when carrying out electroplating.

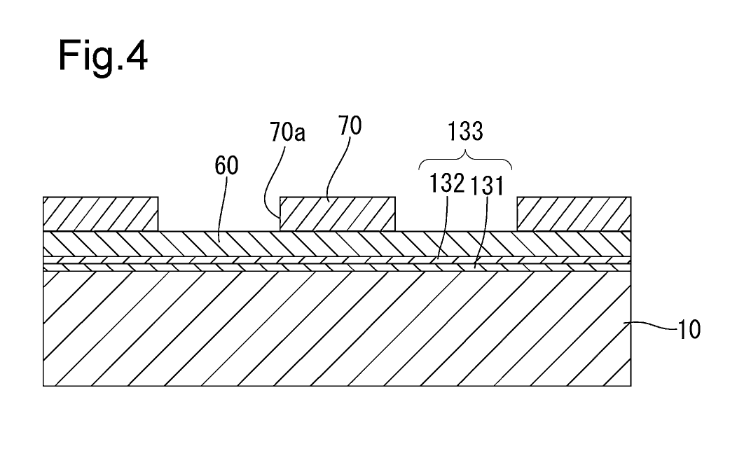

Next, as shown in FIG. 4, after having formed a resist film 60 on the seed layer 133, a photomask 70, having a pattern identical to the wiring circuit pattern to be formed, is arranged so as to oppose the resist film 60.

A dry film resist, for example, can be used for the resist film 60. The resist film 60 can be provided on the seed layer 133 by lamination, for example.

The photomask 70 has an opening 70a for allowing the passage of light such as ultraviolet light. In the case the resist film 60 is of the negative type, namely is composed of a resin that cures in a region irradiated with light, when light is radiated onto the resist film 60 through the opening 70a of the photomask 70, a light-irradiated region irradiated by the light is cured, while a non-light-irradiated region not irradiated by the light is not cured.

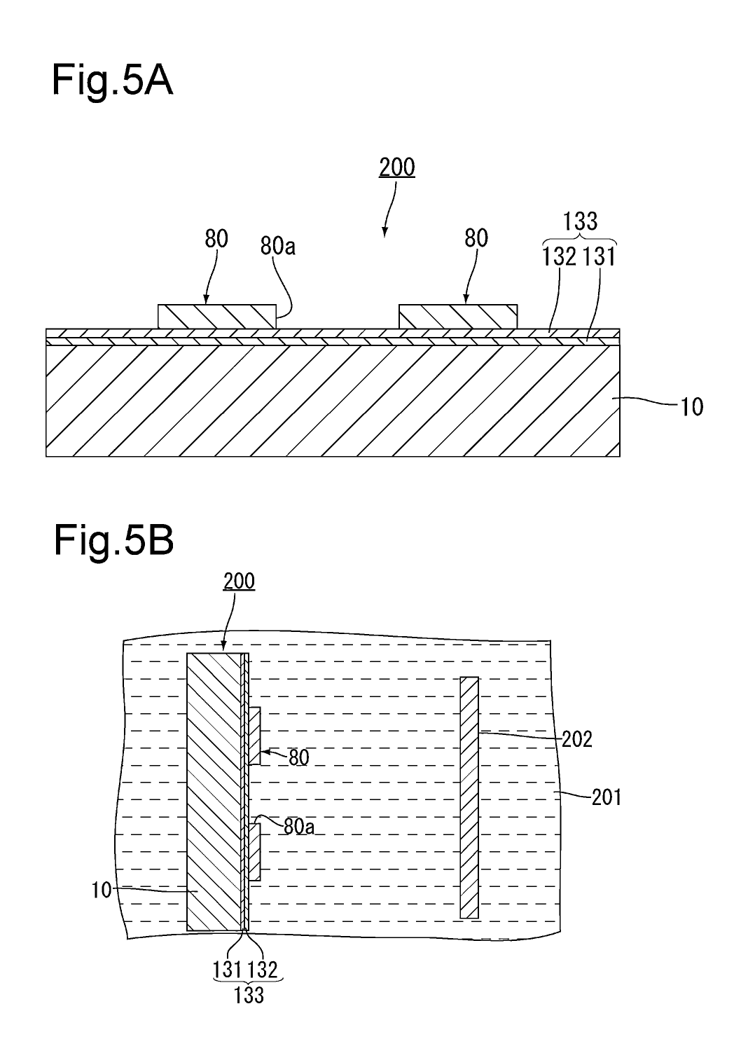

When the photomask 70 is removed and the resist film 60 is developed using a developing solution, the light-irradiated region remains while the non-light-irradiated region is removed as shown in FIG. 5A. A plating resist 80 is formed in this manner (plating resist formation step) and a resist pattern 200 is obtained. Furthermore, in the plating resist 80, the portion from which the non-light-irradiated region has been removed becomes an opening 80a for exposing the seed layer 133. The pattern shape of the opening 80a is the same as the pattern shape of the wiring circuit 30 to be formed.

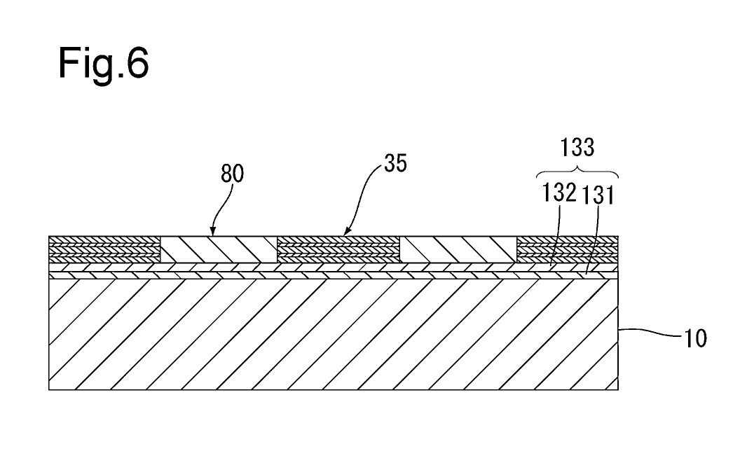

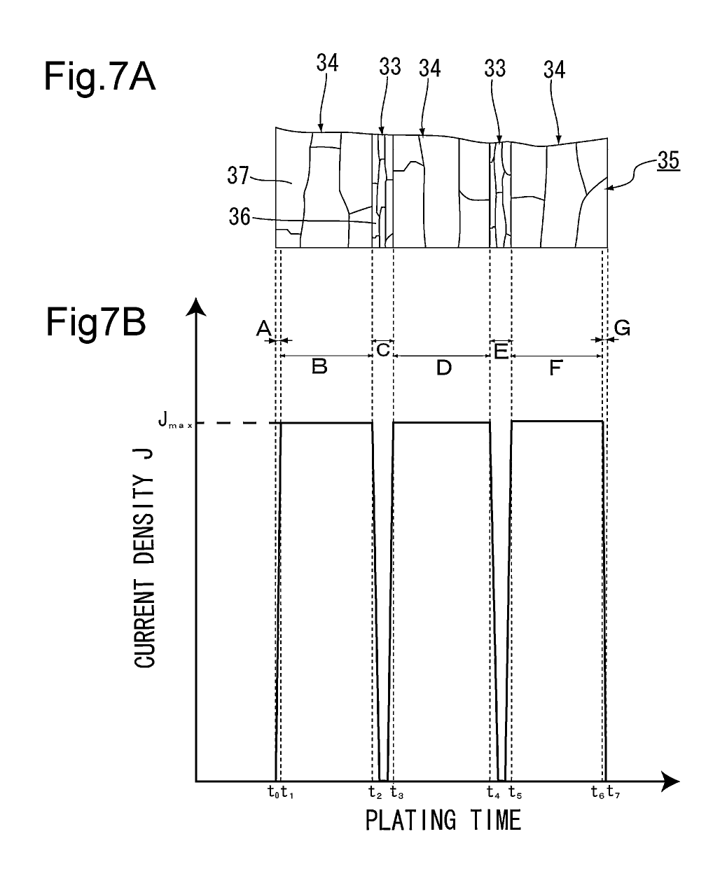

Next, as shown in FIG. 5B, the resist pattern 200 is immersed in an electroplating bath 201. An anode 202 serving as the other electrode among the pair of electrodes used when carrying out electroplating is also immersed in the electroplating bath 201 (see FIG. 5B). A current density is then applied between the immersed electrode and the sheet layer 133. At this time, if the magnitude of the current density is periodically changed, the structure of the precipitated metal also changes periodically. For example, if a pulsed current density is applied, the laminate 35 is formed on the seed layer 133 as shown in FIG. 6. In FIGS. 1 and 2, the number of layers of the first metal layer 33 is two, and the number of layers of the second metal layer 34 is three. In this case, current density pulses are applied three times as shown in FIG. 7B. Here, the time periods during which the current density pulses are applied can be divided into the following seven time periods A to G as shown in FIG. 7A and FIG. 7B.

(1) Time period A: Current density increases from zero to Jₘₐₓ (t=t₀ to t₁)

(2) Time period B: Current density constant at Jₘₐₓ (t=t₁ to t₂)

(3) Time period C: Current density decreases from Jₘₐₓ and after reaching zero, increases and returns to Jₘₐₓ (t=t₂ to t₃)

(4) Time period D: Current density constant at Jₘₐₓ (t=t₃ to t₄)

(5) Time period E: Current density decreases from Jₘₐₓ and after reaching zero, increases and returns to Jₘₐₓ (t=t₄ to t₅)

(6) Time period F: Current density constant at Jₘₐₓ (t=t₅ to t₆)

(7) Time period G: Current density decreases from Jₘₐₓ and reaches zero (t=t₆ to t₇)

Here, in cases in which current density is large, the average grain size of metallic crystal grains can be increased, while in cases in which current density is small, the average grain size of metallic crystal grains can be decreased. In time periods C and E, since the average current density within the precipitation time of metallic crystal grains is smaller than current density Jₘₐₓ in regions B, D and F, in time periods B, D and F, the second metal layers 34 are formed that contain the second metallic crystal grains 37, while during time periods C and E, the first metal layers 33 are formed that contain the first metallic crystal grains 36 having a smaller average grain size than the second metallic crystal grains 37 of the second metal layers 34 formed during time periods B, D and F. The wiring circuit 30 is formed in this manner (wiring circuit formation step). Furthermore, although the average grain size of metallic crystal grains during time periods A and G is theoretically small, since the duration of time periods A and G is short, this does not conspicuously appear in the cross-section shown in FIG. 7A.

At this time, the maximum value of pulsed current density is the current density Jₘₐₓ applied during time periods B, D and F, and Jₘₐₓ is preferably 4.0 A/dm² or less and more preferably 3.0 A/dm² or less. In this case, in comparison with the case in which Jₘₐₓ exceeds 4.0 A/dm², there are the advantages of being able to obtain a plating film that is fine and more superior in terms of mechanical strength and facilitating the obtaining of a layered crystal structure.

However, the current density Jₘₐₓ is preferably 1.0 A/dm² or more and more preferably 2.0 A/dm² or more. In this case, in comparison with the case of the current density Jₘₐₓ being less than 1.0 A/dm², there are the advantages of being able to shorten plating time as well as allowing plating equipment to be reduced in size and processing time to be shortened.

In addition, in order to make the shape of the first metallic crystal grains 36 and the second metallic crystal grains 37 layered, and make the average value of the length a in a direction X parallel to the main surface 10a of the first insulating substrate 10 in the first metallic crystal grains 36 and the second metallic crystal grains 37 greater than the average value of the length b along a direction Y perpendicular to the main surface 10a of the first insulating substrate 10, the current density during plating is made to be 4.0 A/dm² or less and suitable additives such as a glossing agent or flattening agent are added to the plating solution.

The durations of the time periods A to G can be suitably altered corresponding to the thickness of the first metal layers 33 and the second metal layers 34 to be formed.

Furthermore, in order to form five or more layers each consisting of the first metal layer 33 or to form five or more layers each consisting of the second metal layer 34, pulsed current density is applied five times or more.

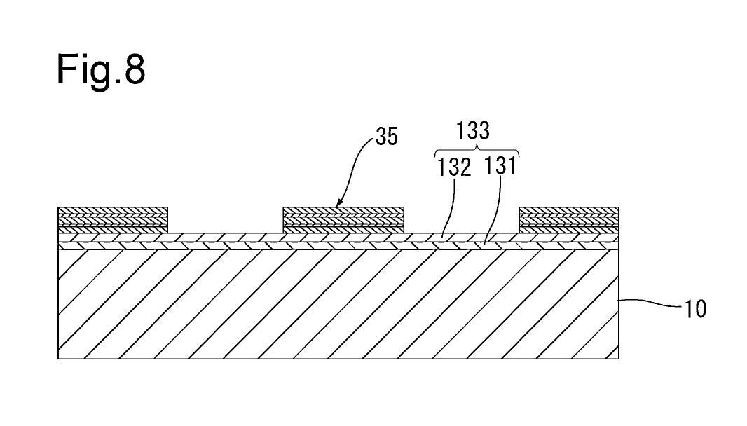

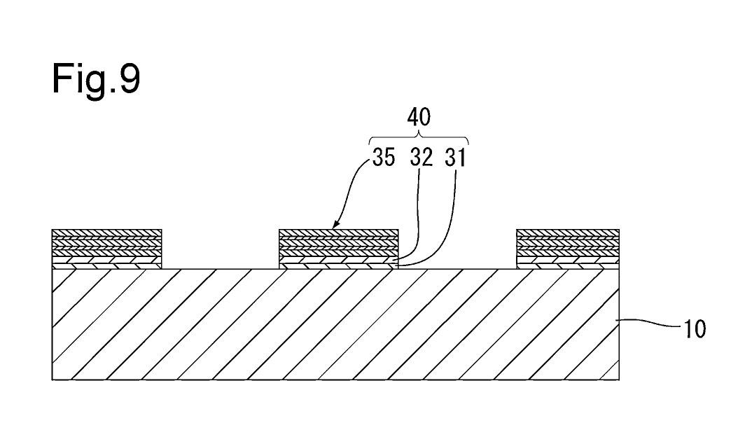

Next, as shown in FIG. 8, the plating resist 80 is stripped (resist stripping step) followed by removal of the exposed seed layer 133 as shown in FIG. 9.

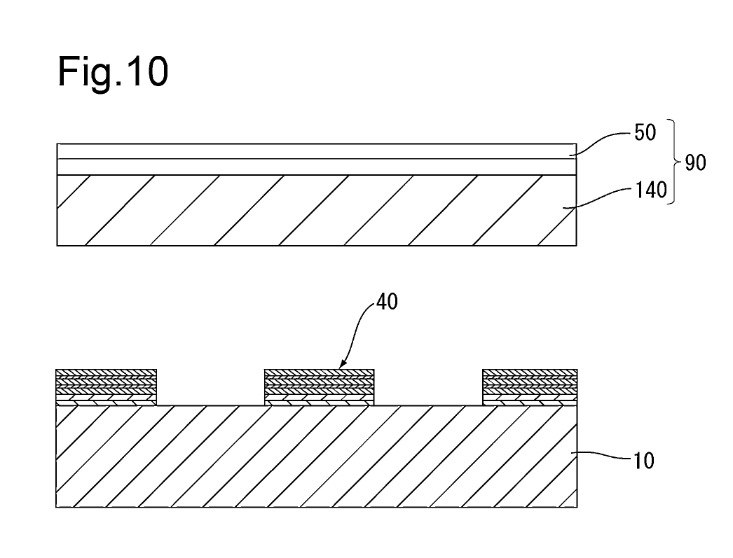

Next, as shown in FIG. 10, a protective cover 90 is prepared in which an adhesive layer 140 is provided on the second insulating substrate 50, and is superimposed on the wiring circuit 30 with this adhesive layer 140 of the protective cover 90 facing the wiring circuit 30.

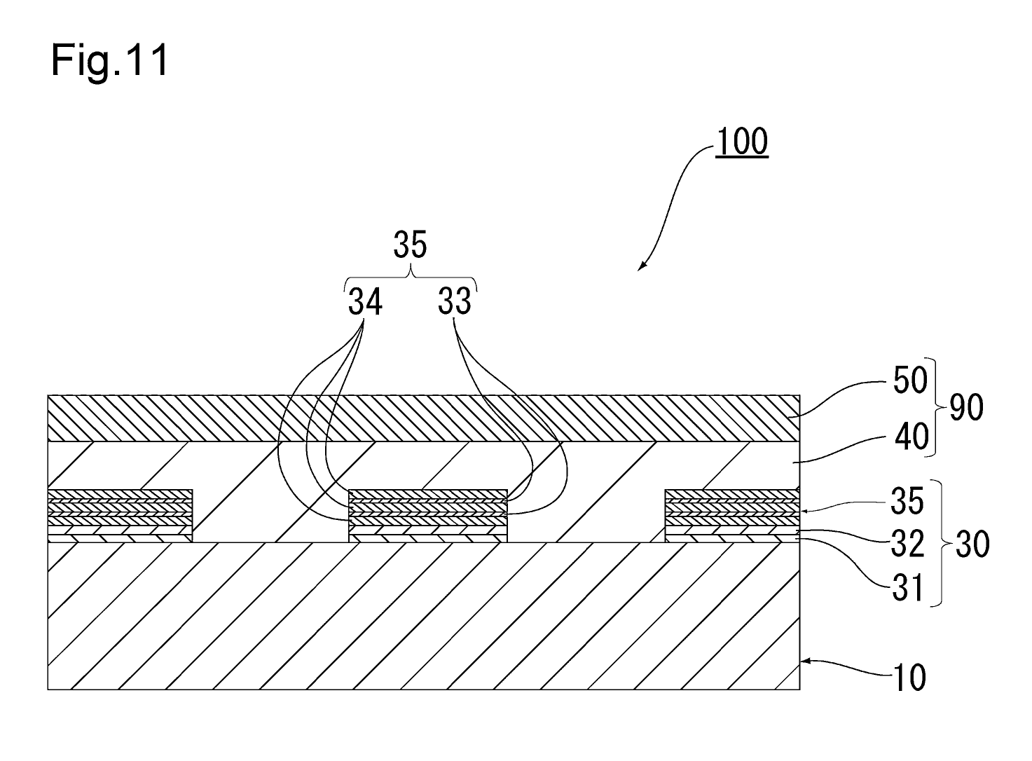

Continuing, the second adhesive layer 140 is interposed between the second insulating substrate 50 and the first insulating substrate 10, and the protective cover 90 is affixed to the wiring circuit 30 by hot pressing. As a result, the adhesive layer 140 is cured and becomes the adhesion layer 40 as shown in FIG. 11. In addition, the first seed layer 131 becomes the metal thin film 31, and the second seed layer 132 becomes the metal thin film 32. The flexible printed circuit board 100 is obtained in this manner.

The present invention is not limited to the above-mentioned embodiments. For example, although the wiring circuit 30 is only formed on the main surface 10a on one side of the first insulating substrate 10 in the above-mentioned embodiments, the wiring circuit 30 may also be formed on a main surface of the first insulating substrate 10 on the opposite side from the main surface 10a.

In addition, in the above-mentioned embodiments, although the wiring circuit 30 is covered with the adhesion layer 40, and the second insulating substrate 50 is further provided on the adhesion layer 40, the adhesion layer 40 and the second insulating substrate 50 are not necessarily required, and can be omitted.

Moreover, although the wiring circuit 30 is formed directly on the first insulating substrate 10 in the above-mentioned embodiments, the wiring circuit 30 is not necessarily required to be formed directly on the first insulating substrate 10 provided the wiring circuit 30 is formed on the side of the main surface 10a of the first insulating substrate 10. Namely, the wiring circuit 30 may be formed on the main surface 10a of the first insulating substrate 10 through an adhesion layer. Furthermore, in the case of forming the wiring circuit 30 on the main surface 10a of the first insulating substrate 10 through an adhesion layer, rolled copper foil or electrolytic copper foil is used for the first metal layer 33 and the second metal layer 34.

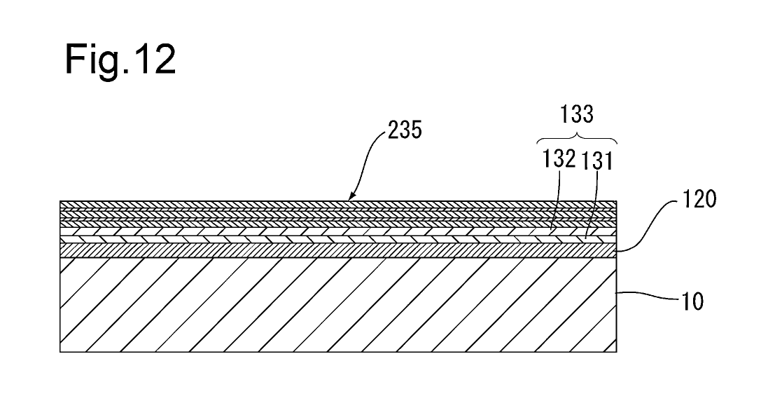

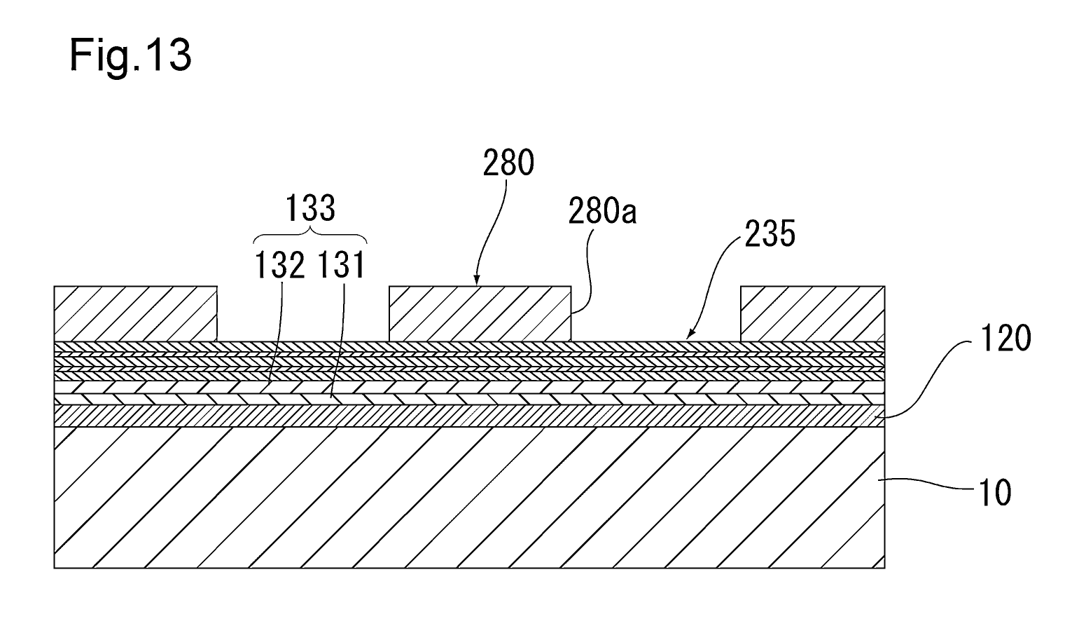

Moreover, although the flexible printed circuit board 100 is produced using a semi-additive process in the above-mentioned embodiments, the flexible printed circuit board 100 can also be produced using a subtractive process. More specifically, copper foil is hot-pressed onto the first insulating substrate 10 through an adhesive layer 120 composed of an adhesive such as a thermosetting resin to obtain the seed layer 133, and as shown in FIG. 12, a pulsed current density is applied multiple times between the seed layer 133 and an electrode using electroplating to form a plating layer 235 over the entire surface of the seed layer 133 (plating layer formation step). Namely, panel plating is carried out. Continuing, as shown in FIG. 13, an etching resist 280 in which an opening 280a that exposes the plating layer 235 is formed and which has a shape corresponding to the wiring circuit 30 is formed on the plating layer 235 (etching resist formation step). Continuing, after forming the wiring circuit 30 by etching the exposed plating layer 235 and the seed layer 133 (wiring circuit formation step), the etching resist 280 is stripped (resist stripping step). The flexible printed circuit board 100 can also be manufactured in this manner.

### EXAMPLES

Although the following provides a more specific explanation of the contents of the present invention by listing examples and comparative examples, the present invention is not limited to the following examples.

### Example 1

A polyimide film (trade name: Kapton EN, Du Pont-Toray Co., Ltd.) having a thickness of 25 μm was prepared. An Ni film was formed on this polyimide film by sputtering. At this time, the thickness of the Ni film was 0.2 μm. Continuing, a Cu film was formed on the Ni film by sputtering. The Cu film was formed to have a thickness of 2 μm. A polyimide film with a seed layer has Ni and Cu films formed by sputtering.

Next, an acrylic-based negative film resist (trade name: Sunfort UFG-252, Asahi Kasei Corp.) was laminated at 110° C. onto the seed layer of the polyimide film with the seed layer. Continuing, UV exposure and development were sequentially carried out through a photomask having a wiring pattern corresponding to metal wiring having a circuit width of 50 μm, space of 100 μm and pitch of 150 μm to form a plating resist having a thickness of 25 μm. At this time, development was carried out by spraying a sodium carbonate solution having a concentration of 2% at 30° C.

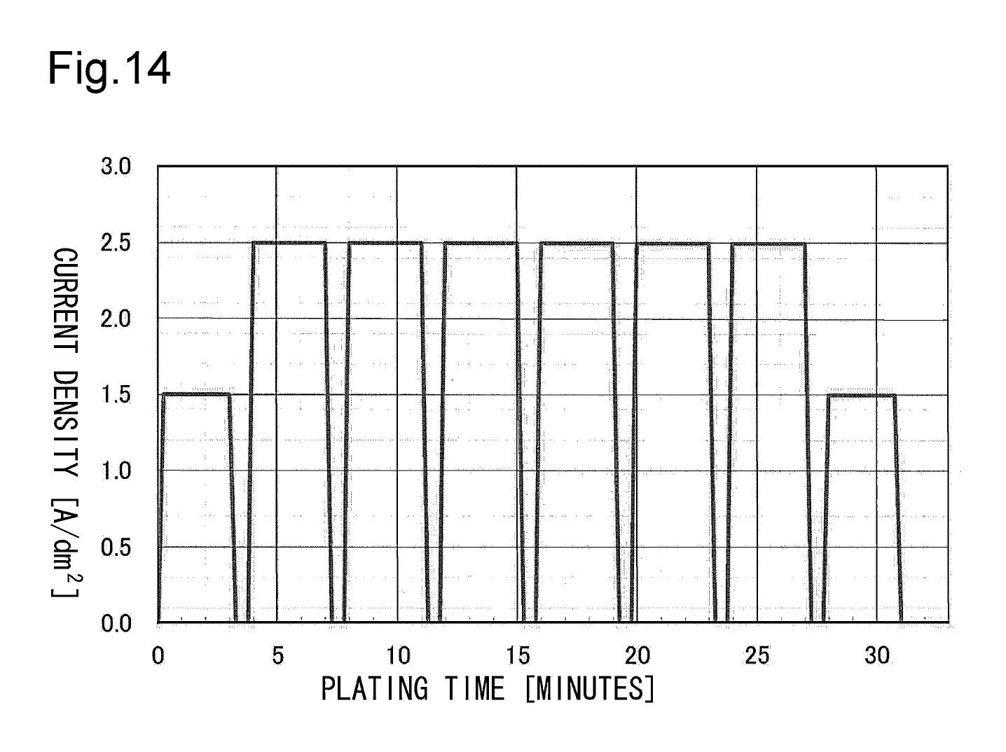

Next, pattern plating was carried out using an electroplating bath (copper sulfate plating, trade name: CLX, Meltex, Inc.) to obtain a laminate composed of 8 second metal layers and first metal layers respectively provided between adjacent second metal layers. During pattern plating, the precipitated structure of Cu plating was fluctuated periodically by applying a pulsed current density 8 times. The current density was specifically applied so as to have the profile shown in FIG. 14. In FIG. 14, the specific durations of the time periods corresponding to current density were as indicated below. Furthermore, in FIG. 14, the reason for lowering the current density of the first second metal layer was to prevent abnormal precipitation of the plating film (in the form of branching crystals referred to as dendrites), while the reason for lowering the current density of the eighth second layer was to control total plating thickness.

(1) Time during which current density was made to be 1.5 A/dm²: 2.5 minutes

(2) Time during which current density was made to be 2.5 A/dm²: 3 minutes

(3) Time during which current density was made to be 0 A/dm²: 30 seconds

(4) Time during which current density was increased or decreased between 0 A/dm² and 2.5 A/dm²: 15 seconds

In addition, the thicknesses of the first metal layers and the second metal layers were respectively as indicated below so that the total thickness of the laminate was 18 μm.

Thickness of first metal layers: 0.2 μm

Thickness of second metal layers: 2.8 μm

Next, the plating resist was stripped by spraying with a sodium hydroxide solution having a concentration of 3.0% at 50° C.

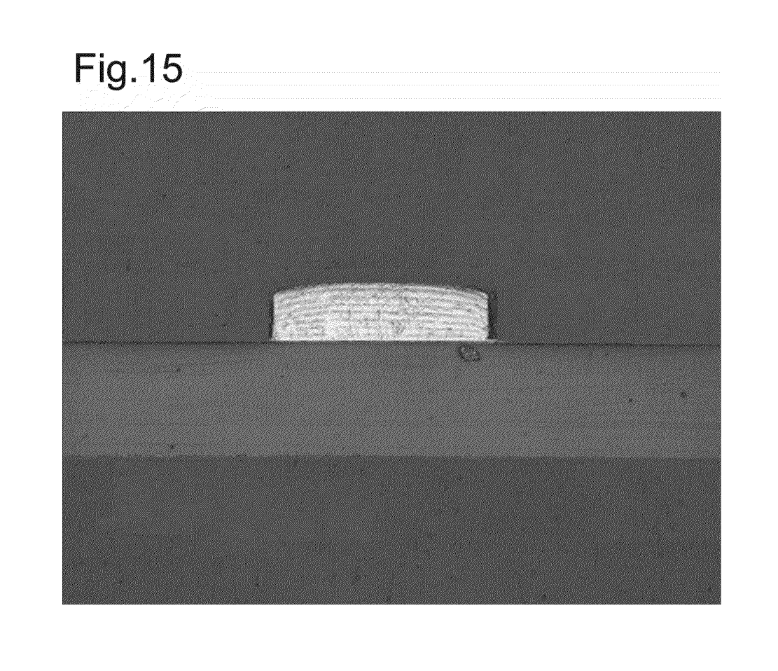

Next, the seed layer exposed between the circuits was removed using a sulfuric acid and aqueous hydrogen peroxide-based copper soft etching solution and a nitric acid and aqueous hydrogen peroxide-based nickel etching solution. Thus, a wiring circuit was formed on one side of the polyimide film to obtain a polyimide film with a circuit. At this time, the polyimide film with the circuit was embedded in epoxy-based resin followed by polishing a cross-section thereof. Subsequently, the polished cross-section was soft-etched using an ammonium hydroxide-hydrogen peroxide-based etching solution, and the structure of the first metal layers and the second metal layers was observed with a scanning electron microscope. The observed structure is shown in FIG. 15. The average grain size of the first metallic crystal grains in the first metal layers, and an area percentage (R1), which is the ratio of the area occupied by the layered first metallic crystal grains in which the length in a direction parallel to the main surface of the polyimide film is greater than the length in a direction perpendicular to the main surface of the polyimide film among the total area of the first metallic crystal grains in the first metal layers observed, were measured. Similarly, the average grain size of the second metallic crystal grains in the second metal layers, and an area percentage (R2), which is the area of the area occupied by the layered second metallic crystal grains in which the length in a direction parallel to the main surface of the polyimide film is greater than the length in a direction perpendicular to the main surface of the polyimide film among the total area of the second metallic crystal grains in the second metal layers observed, were measured. The results are shown in Table 1. Furthermore, in Table 1, the reasons for lowering the current density of the first second metal layer and the current density of the eighth second metal layer are as previously described. However, in this case, a difference in average grain size theoretically occurs since current density differs between the first and eighth layers and the second to seventh layers of the second metal layers. An accompanying difference in average grain size also theoretically occurs between the first and seventh layers and the second through sixth layers of the first metal layers. However, remarkable differences in average grain size were not confirmed experimentally.

After superimposing a protective cover, which was obtained by preliminarily applying an adhesive to a thickness of 20 μm onto a polyimide film having a thickness of 12.5 μm, on the polyimide film with the circuit obtained in the manner described above so that the wiring circuit and adhesive layer are in contact, the polyimide film with the circuit and the protective cover were subjected to hot pressing. At this time, hot pressing was carried out under conditions of 150° C. and 20 kg/cm² for 15 minutes. A flexible printed circuit board was obtained in this manner.

### Comparative Example 1

A flexible printed circuit board was fabricated in the same manner as Example 1 with the exception of arranging thermoplastic polyimide (TPI) between electrolytic copper foil (trade name: F2-WS, Furukawa Electric Co., Ltd.) and a polyimide film followed by heating and pressing to form a polyimide film with a circuit by hot pressing and immobilizing the copper foil and polyimide film.

### Comparative Example 2

A flexible printed circuit board was fabricated in the same manner as Example 1 with the exception of arranging thermoplastic polyimide (TPI) between rolled copper foil (trade name: HA Foil, Nippon Mining & Metals Corp.) and a polyimide film followed by heating and pressing to form a polyimide film with a circuit by hot pressing and immobilizing the copper foil and polyimide film.

The flexible printed circuit boards of Example 1 and Comparative Examples 1 and 2 obtained in the manner described above were evaluated for bending resistance.

(MIT Folding Endurance Test)

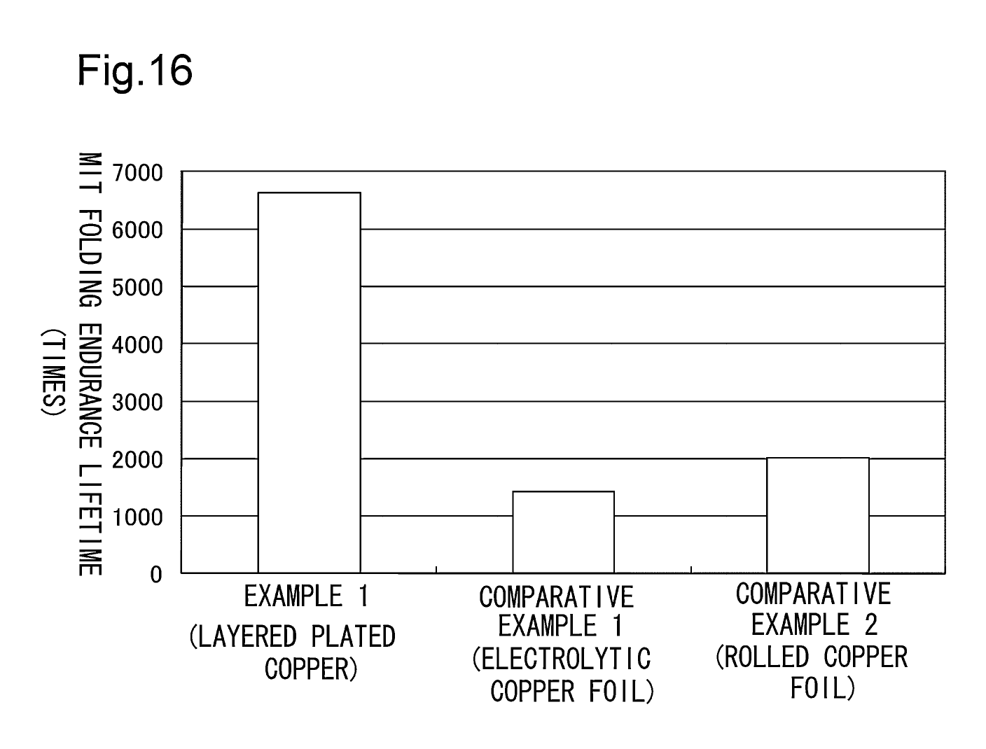

The flexible printed circuit boards of Example 1 and Comparative Examples 1 and 2 were evaluated for bending resistance by carrying out the MIT folding endurance test in compliance with ASTM D2176. The results are shown in Table 1 and FIG. 16. Furthermore, testing conditions were as indicated below.

Bending radius: R=0.38 mm

Bending rate: 175 times/minute

(IPC Bending Test)

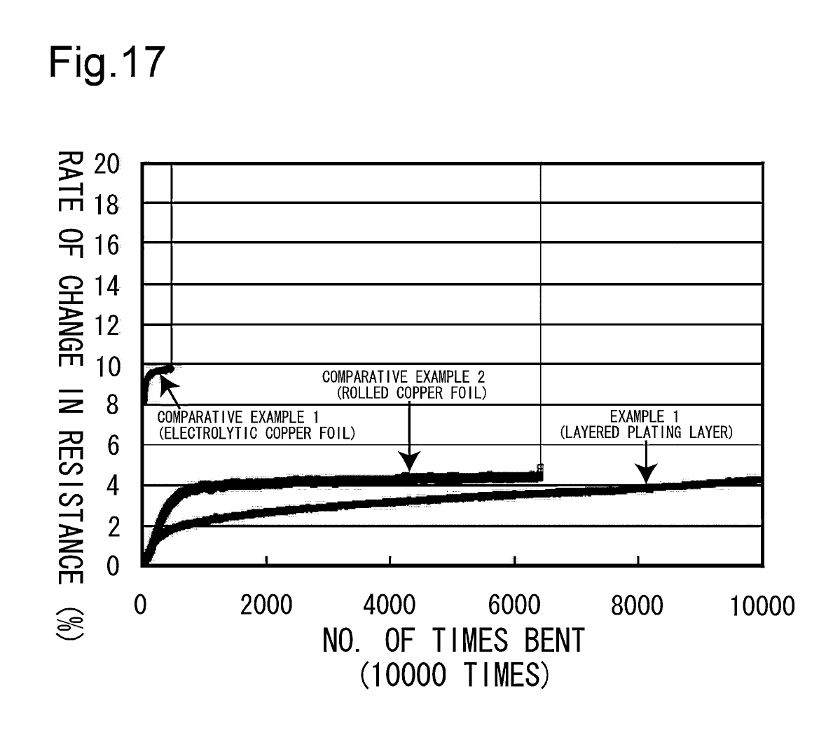

The flexible printed circuit boards of Example 1 and Comparative Examples 1 and 2 were evaluated for bending resistance by carrying out the IPC bending test in compliance with IPC standard TM-650. The results are shown in Table 1 and FIG. 17. Furthermore, testing conditions were as indicated below.

Measuring current: 5 mA

Bending radius: R=0.2 mm

Stroke: 15 mm

Bending rate: 1500 times/minute

Temperature: 80° C.

Bending direction: Bent so that the surface of the protective cover faces to the inside

TABLE 1

| | First Metal | | Second Metal | | | |
|---|---|---|---|---|---|---|
| | Layers | | Layers | | | |
| | First | | Second | | Performance Evaluation | |
| | metal | | metal | | MIT folding | IPC bending |
| | layer | | layer | | endurance test | test |
| | average | | average | | MIT folding | No. of times |
| | grain | | grain | | endurance | bent until |
| | size | R1 | size | R2 | lifetime | disconnection |
| | (μm) | (%) | (μm) | (%) | (times) | (10000 times) |
| Example 1 | 0.2 | 80 | 2.5 | 85 | 6600 | No |
| | | | | | | disconnections |
| | | | | | | at 10000 |
| Comp. | — | — | — | — | 1400 | 500 |
| Ex. 1 | | | | | | |
| Comp. | — | — | — | — | 2000 | 7000 |
| Ex. 2 | | | | | | |

According to the results of Table 1 and FIG. 16, the MIT folding endurance test lifetime of the flexible printed circuit board of Example 1 was considerably greater than the MIT folding endurance test lifetime of the flexible printed circuit board of Comparative Example 1 that used electrolytic copper foil for the wiring circuit. In addition, the MIT folding endurance test lifetime of the flexible printed circuit board of Example 1 was also considerably greater than the MIT folding endurance test lifetime of the flexible printed circuit board of Comparative Example 2 that used rolled copper foil for the wiring circuit.

In addition, according to the results shown in Table 1 and FIG. 17, since disconnections did not occur in the flexible printed circuit board of Example 1 even after bending 100 million times, it was found that the number of times it can be bent was equal to or greater than 100 million times. In contrast, the number of times the flexible printed circuit board of Comparative Example 1 that used electrolytic copper foil for the wiring circuit was bent until disconnection occurred was about 5 million times, while that of the flexible printed circuit board of Comparative Example 2 that used rolled copper foil for the wiring circuit was about 70 million times.

On the basis of these findings, the flexible printed circuit board of the present invention was confirmed to have superior bending resistance.

### EXPLANATION OF REFERENCE NUMERALS

10 First insulating substrate (insulating substrate)
10a Main surface
30 Wiring circuit
33 First metal layers
34 Second metal layers
35 Laminate
36 First metallic crystal grains
37 Second metallic crystal grains
80 Plating resist
80a Opening
100 Flexible printed circuit board
131 First seed layer
132 Second seed layer
133 Seed layer
235 Plating layer
280 Etching resist
280a Opening

What is claimed is:

1. A flexible printed circuit board provided with an insulating substrate and a wiring circuit provided on at least one main surface side of the insulating substrate, wherein
the wiring circuit has a laminate having a first metal layer that contains first metallic crystal grains and a second metal layer that is adjacent to the first metal layer and contains second metallic crystal grains, with the first metal layer and the second metal layer being laminated along a direction perpendicular to the main surface of the insulating substrate, and
the average grain size of the first metallic crystal grains is smaller than the average grain size of the second metallic crystal grains.

2. The flexible printed circuit board according to claim 1, wherein the length in a direction parallel to the main surface of the insulating substrate in the first metallic crystal grains and the second metallic crystal grains is greater than the length along a direction perpendicular to the main surface of the insulating substrate in 50% or more of the first metallic crystal grains and the second metallic crystal grains.

3. The flexible printed circuit board according to claim 1, wherein the laminate has five or more layers each consisting of the first metal layer and five or more layers each consisting of the second metal layer, and in the laminate, the first metal layers and the second metal layers are alternately laminated.

4. The flexible printed circuit board according to claim 1, wherein the first metal layer and the second metal layer are copper alloy foil containing 0.05% by weight or more of at least one type of element selected from the group consisting of Sn, Zn, Be, Cd, Ag and Nb.

5. A production method of a flexible printed circuit board provided with an insulating substrate and a wiring circuit provided on at least one main surface side of the insulating substrate,
the method comprising:
a seed layer formation step of forming a seed layer on at least one main surface side of the insulating substrate;
a plating resist formation step of forming a plating resist in which an opening that has a shape corresponding to the wiring circuit and exposes the seed layer is formed on the seed layer;
a wiring circuit formation step of forming the wiring circuit on the seed layer by applying a pulsed current density at least once between the seed layer and an electrode by means of electroplating;
a plating resist stripping step of stripping the plating resist; and
a seed layer removal step of removing a portion of the seed layer covered by the plating resist, wherein
the wiring circuit has a laminate having a first metal layer that contains first metallic crystal grains and a second metal layer that is adjacent to the first metal layer and contains second metallic crystal grains, with the first metal layer and the second metal layer being laminated along a direction perpendicular to the main surface of the insulating substrate, and
the average grain size of the first metallic crystal grains is smaller than the average grain size of the second metallic crystal grains.

6. A production method of a flexible printed circuit board provided with an insulating substrate and a wiring circuit provided on at least one main surface side of the insulating substrate,
the method comprising:
a seed layer formation step of forming a seed layer on at least one main surface side of the insulating substrate;
a plating layer formation step of forming a plating layer on the seed layer by applying a pulsed current density at least once between the seed layer and an electrode by means of electroplating;
an etching resist formation step of forming on the plating layer an etching resist in which an opening is formed that exposes the plating layer and which has a shape corresponding to the wiring circuit;
a wiring circuit formation step of forming the wiring circuit by etching the exposed plating layer and the seed layer; and
a resist stripping step of stripping the etching resist, wherein
the plating layer has a laminate having a first metal layer that contains first metallic crystal grains and a second metal layer that is adjacent to the first metal layer and contains second metallic crystal grains, with the first metal layer and the second metal layer being laminated along a direction perpendicular to the main surface of the insulating substrate, and
the average grain size of the first metallic crystal grains is smaller than the average grain size of the second metallic crystal grains.

7. The production method of a flexible printed circuit board according to claim 5, wherein the maximum value of the pulsed current density is 4.0 A/dm² or less.

8. The production method of a flexible printed circuit board according to claim 5, wherein the pulsed current density is applied five times or more.
